(19) United States
(12) Patent Application Publication
(10) Pub. No.: US 2026/0204867 A1
(43) Pub. Date: Jul. 16, 2026

(54) LIGHT EMITTING DEVICE AND DISTANCE MEASURING DEVICE

(71) Applicant: SONY SEMICONDUCTOR SOLUTIONS CORPORATION, KANAGAWA (JP)

(72) Inventors: HIROSHI YOSHIDA, TOKYO (JP); YUTA SANO, KANAGAWA (JP)

(21) Appl. No.: 19/135,372

(22) PCT Filed: Oct. 19, 2023
(86) PCT No.: PCT/JP2023/037932

§ 371 Date: Jun. 3, 2025

(30) Foreign Application Priority Data
Dec. 9, 2022 (JP) 2022-197072

(51) Int. Cl. H01S 5/062; G01S 7/481; H01S 5/183

(52) U.S. Cl. CPC H01S 5/062; G01S 7/4814; H01S 5/18308

(57) ABSTRACT

An emission direction of laser light is controlled with a simpler structure. A light emitting device includes: a laser light generation unit that causes laser light to resonate in a resonance area on a first surface and a second surface facing each other, and emits the laser light from the first surface; a substrate that is provided on the first surface of the laser light generation unit, and absorbs a part of the emitted laser light while transmitting the laser light; and a plurality of control electrodes that is provided on the second surface of the laser light generation unit, and faces each other with the resonance area interposed between the control electrodes.

### TECHNICAL FIELD

The present disclosure relates to a light emitting device and a distance measuring device.

### BACKGROUND ART

In recent years, in a moving body such as an automobile or a drone, a distance to a measurement object existing around the moving body is measured by a distance measuring device. Light detection and ranging (LiDAR) used in such a distance measuring device is desired to scan with light with which the measurement object is irradiated.

For example, in the LiDAR, a mechanical optical scanning method that switches an optical path using a mirror driven by an actuator has been put into practical use. In addition, a non-mechanical optical scanning method that sweeps in the emission angle of light using a photonic crystal, an electro-optic crystal, a slow light waveguide, or the like has been studied.

For example, Patent Document 1 below discloses a light deflection device that deflects an emission direction of light by diffracting light using a slow light waveguide.

### CITATION LIST

### Patent Document

Patent Document 1: Japanese Patent Application Laid-Open No. 2022-82100

### SUMMARY OF THE INVENTION

### Problems to be Solved by the Invention

However, in the above technology disclosed in Patent Document 1, a slow light waveguide subjected to micromachining finer than the wavelength of emitted light is used to deflect the emission direction of light. For this reason, the complexity in manufacturing steps and the manufacturing cost of the light deflection device will rise.

Thus, a light emitting device capable of controlling the emission direction of laser light with a simpler structure is desired.

### Solutions to Problems

According to the present disclosure, there is provided a light emitting device including: a laser light generation unit that causes laser light to resonate in a resonance area on a first surface and a second surface facing each other, and emits the laser light from the first surface; a substrate that is provided on the first surface of the laser light generation unit, and absorbs a part of the emitted laser light while transmitting the laser light; and a plurality of control electrodes that is provided on the second surface of the laser light generation unit, and faces each other with the resonance area interposed between the control electrodes.

In addition, according to the present disclosure, there is provided a distance measuring device including a light projecting unit configured by arranging a plurality of light emitting devices in an array, in which each of the plurality of light emitting devices includes: a laser light generation unit that causes laser light to resonate in a resonance area on a first surface and a second surface facing each other, and emits the laser light from the first surface; a substrate that is provided on the first surface of the laser light generation unit, and absorbs a part of the emitted laser light while transmitting the laser light; and a plurality of control electrodes that is provided on the second surface of the laser light generation unit, and faces each other with the resonance area interposed between the control electrodes.

In addition, according to the present disclosure, there is provided a distance measuring device including: a light projecting unit that is configured by arranging a plurality of light emitting devices in an array, and projects projection light onto an object; and a light receiving unit that receives the projection light reflected by the object, in which each of the plurality of light emitting devices includes: a laser light generation unit that causes laser light to resonate in a resonance area on a first surface and a second surface facing each other, and emits the laser light from the first surface; a substrate that is provided on the first surface of the laser light generation unit, and absorbs a part of the emitted laser light while transmitting the laser light; and a plurality of control electrodes that is provided on the second surface of the laser light generation unit, and faces each other with the resonance area interposed between the control electrodes.

### BRIEF DESCRIPTION OF DRAWINGS

FIG. 1 is an explanatory diagram illustrating a top surface configuration and a cross-sectional configuration of a light emitting device according to a first embodiment of the present disclosure.

FIG. 2 is an explanatory diagram illustrating a relationship between a voltage applied to control electrodes and an optical profile of laser light emitted from a laser light generation unit.

FIG. 3 is an explanatory diagram illustrating a correspondence relationship between the optical profile of the laser light and a propagation direction of the laser light.

FIG. 4 is a block diagram illustrating a circuit configuration of the light emitting device according to the first embodiment.

FIG. 5 is an explanatory diagram illustrating a cross-sectional configuration of a first modification of the light emitting device according to the first embodiment.

FIG. 6 is an explanatory diagram illustrating a planar configuration of detection electrodes provided on a substrate.

FIG. 7 is a circuit diagram illustrating a second modification of the light emitting device according to the first embodiment.

FIG. 8 is an explanatory diagram illustrating a distance measuring device according to a first configuration example of a second embodiment of the present disclosure.

FIG. 9 is an explanatory diagram illustrating a top surface configuration and a cross-sectional configuration of a light emitting device according to the first configuration example of the second embodiment.

FIG. 10 is an explanatory diagram illustrating a distance measuring device according to a second configuration example of the second embodiment.

FIG. 11 is a block diagram illustrating a functional configuration of the distance measuring device according to the second configuration example of the second embodiment.

FIG. 12 is an explanatory diagram illustrating a relationship between reflected light of laser light emitted from the light emitting device and light receiving elements.

FIG. 13 is an explanatory diagram illustrating deflection control for laser light emitted from the light emitting device in FIG. 12.

FIG. 14 is an explanatory diagram illustrating a cross-sectional configuration of a modification of the light emitting device according to the second embodiment.

### MODE FOR CARRYING OUT THE INVENTION

Preferred embodiments of the present disclosure will be hereinafter described in detail with reference to the accompanying drawings. Note that, in the present description and the drawings, constituent elements having substantially the same functional configurations will be denoted with the same reference signs, and redundant descriptions will be omitted.

Note that the description will be given in the following order.
1. First Embodiment
1.1. Configuration of Light Emitting Device
1.2. Modifications
2. Second Embodiment
2.1. Configuration of Distance Measuring Device
2.2. Modifications

### 1. First Embodiment

### 1.1. Configuration of Light Releasing Device

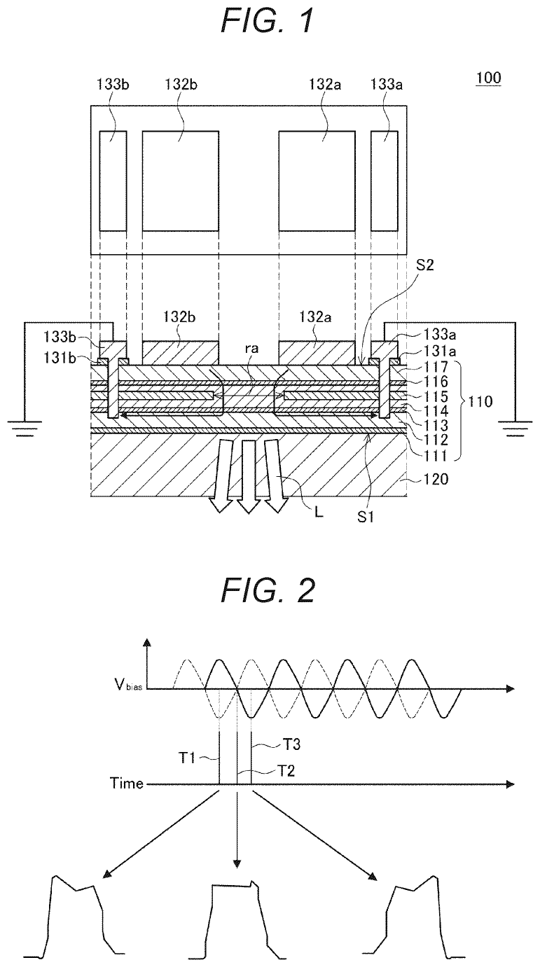

A configuration of a light emitting device according to a first embodiment of the present disclosure will be described with reference to FIG. 1. FIG. 1 is an explanatory diagram illustrating a top surface configuration and a cross-sectional configuration of a light emitting device 100 according to the present embodiment.

As illustrated in FIG. 1, the light emitting device 100 includes a laser light generation unit 110, a substrate 120, a plurality of control electrodes 132a and 132b, and a plurality of ground electrodes 133a and 133b.

The laser light generation unit 110 is a so-called surface emitting semiconductor laser (vertical cavity surface emitting laser: VCSEL) element. The laser light generation unit 110 is configured by sequentially laminating a buffer layer 111, a first mirror layer 112, a first spacer layer 113, an active layer 114, a second spacer layer 116, and a second mirror layer 117 from a first surface S1 side at which the substrate 120 is provided. The laser light generation unit 110 is, for example, an element that emits laser light L having a wavelength of 940 nm from the first surface S1. Hereinafter, the first surface S1 side will be expressed as a lower side, and a second surface S2 side opposite to the first surface S1 side will be expressed as an upper side.

The buffer layer 111 is a layer that electrically insulates the substrate 120 from the laser light generation unit 110 and is provided on top of the substrate 120. Specifically, the buffer layer 111 may be constituted with a material that has an electrical resistance enough to allow insulation between the substrate 120 and the laser light generation unit 110 to be maintained and can epitaxially grow from the substrate 120. As an example, the buffer layer 111 may be constituted with lightly doped (for example, the doping concentration is 10¹⁵ cm⁻³ or less) gallium arsenide (GaAs). As another example, the buffer layer 111 may be formed by oxygen injection into an aluminum gallium arsenide (AlGaAs) layer or oxidation of the AlGaAs layer.

The first mirror layer 112 is a distributed Bragg reflector (DBR) constituted by a semiconductor multilayer film of a first conductivity type (for example, n-type) and is provided on top of the buffer layer 111. Specifically, the first mirror layer 112 is a multilayer reflective mirror configured by alternately laminating a high refractive index layer and a low refractive index layer with an optical thickness of ¼ of the oscillation wavelength. For example, the first mirror layer 112 is configured by alternately laminating AlGaAs layers (for example, a low refractive index layer constituted with n-Al_{0.9}Ga_{0.1}As and a high refractive index layer constituted with n-Al_{0.3}Ga_{0.7}As) having different Al compositions. The first mirror layer 112 may contain silicon (Si) or the like as a first conductivity type (for example, n-type) impurity.

The first spacer layer 113 is a semiconductor layer of the first conductivity type (for example, n-type) and is provided on top of the first mirror layer 112. The first spacer layer 113 may be constituted with, for example, n-GaAs. The first spacer layer 113 may contain silicon (Si) or the like as a first conductivity type (for example, n-type) impurity.

The active layer 114 has a quantum well structure and is provided on top of the first spacer layer 113. Specifically, the active layer 114 has a quantum well structure formed by alternately laminating a plurality of quantum well layers having a small band gap and barrier layers having a large band gap. The quantum well layer may be constituted with undoped indium gallium arsenide (In_{0.05}Ga_{0.95}As), and the barrier layer may be constituted with undoped Al_{0.1}Ga_{0.9}As, for example.

In addition, a current confinement layer 115 that confines a current flowing through a resonance area ra in the active layer 114 is provided inside the active layer 114. The current confinement layer 115 is a layer having a higher electrical resistance than the active layer 114 and having an opening corresponding to the resonance area ra. The current confinement layer 115 may be constituted with, for example, an insulating material such as silicon oxide (SiO₂) or aluminum oxide (Al₂O₃), or may be constituted by raising the electrical resistance than other areas of the active layer 114 by oxidation. The current confinement layer 115 can further raise the density of the current flowing through the active layer 114 by confining the current flowing through the active layer 114 into the resonance area ra corresponding to the opening of the current confinement layer 115.

The second spacer layer 116 is a semiconductor layer of a second conductivity type (for example, p-type) and is provided on top of the active layer 114. The second spacer layer 116 may be constituted with, for example, p-GaAs. The second spacer layer 116 may contain zinc (Zn), carbon (C), magnesium (Mg), beryllium (Be), or the like as a second conductivity type (for example, p-type) impurity.

The first spacer layer 113 and the second spacer layer 116 are provided to adjust the resonator length between the first mirror layer 112 and the second mirror layer 117. By configuring the first spacer layer 113, the active layer 114, and the second spacer layer 116 such that the sum of the optical thicknesses is equal to the oscillation wavelength (for example, 940 nm), the laser light generation unit 110 can be caused to perform optimum resonance operation.

The second mirror layer 117 is a distributed Bragg reflector (DBR) constituted by a semiconductor multilayer film of the second conductivity type (for example, p-type) and is provided on top of the second spacer layer 116. The second mirror layer 117 is a multilayer reflective mirror configured by alternately laminating a high refractive index layer and a low refractive index layer with an optical thickness of ¼ of the oscillation wavelength. For example, the second mirror layer 117 is configured by alternately laminating AlGaAs layers (for example, a low refractive index layer constituted with p-Al_{0.9}Ga_{0.1}As and a high refractive index layer constituted with p-Al_{0.3}Ga_{0.7}As) having different Al compositions. The second mirror layer 117 may contain zinc (Zn), carbon (C), magnesium (Mg), beryllium (Be), or the like as a second conductivity type (for example, p-type) impurity.

In such a laser light generation unit 110, a current is injected into the active layer 114 having a quantum well structure, whereby spontaneous emission light is produced from the active layer 114. The spontaneous emission light produced in the active layer 114 travels in a laminating direction of the laser light generation unit 110 and is then reflected between the first mirror layer 112 and the second mirror layer 117. Since the first mirror layer 112 and the second mirror layer 117 selectively reflect the light having the oscillation wavelength, the light having the component of the oscillation wavelength in the spontaneous emission light forms a standing wave between the first mirror layer 112 and the second mirror layer 117 and is amplified by the active layer 114. This causes an injection current into the active layer 114 to exceed a threshold value, and consequently, the light forming the standing wave oscillates as a laser and is emitted as the laser light L to the substrate 120 side.

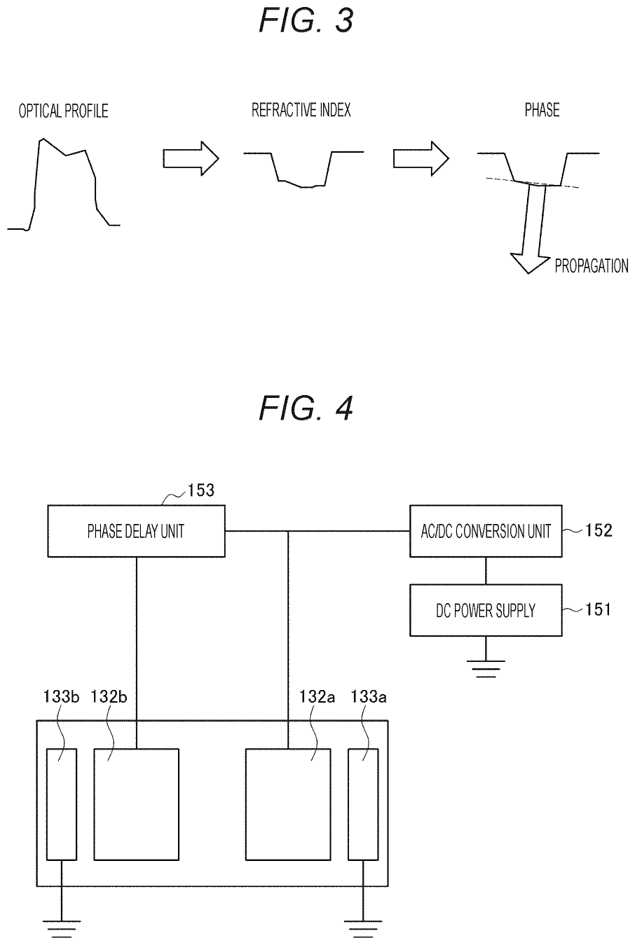

The substrate 120 is a support body for the laser light generation unit 110 and is provided on the first surface S1 side of the laser light generation unit 110. The substrate 120 is constituted with a material that absorbs a part of the laser light emitted from the laser light generation unit 110 while transmitting the laser light, whereby the emission direction of the laser light L emitted from the laser light generation unit 110 can be deflected. The substrate 120 may be, for example, a GaAs substrate of the first conductivity type (for example, n-type). A mechanism of an action of the substrate 120 to deflect the emission direction of the laser light L will be described later with reference to FIGS. 2 and 3. Note that the absorption rate of the substrate 120 for the laser light is controlled by, for example, the doping concentration of the first conductivity type impurity in the substrate 120.

The control electrodes 132a and 132b are separately provided on top of the second surface S2 on an opposite side of the first surface S1 of the laser light generation unit 110 so as to face each other with the resonance area ra interposed therebetween. The control electrodes 132a and 132b are power supply-side electrodes of the light emitting device 100 and are constituted with a conductive material. The control electrodes 132a and 132b may be configured by sequentially laminating titanium-gold (Ti—Au) from the second surface S2 side, for example.

The ground electrodes 133a and 133b are provided corresponding to the control electrodes 132a and 132b, respectively, on top of the second surface S2 of the laser light generation unit 110 via insulating layers 131a and 131b, respectively. Specifically, the ground electrodes 133a and 133b may be provided on opposite sides of the side where the resonance area ra is provided with respect to the corresponding control electrodes 132a and 132b (that is, outer sides with respect to the corresponding control electrodes 132a and 132b) via the insulating layers 131a and 131b, respectively.

The ground electrodes 133a and 133b are electrically connected to a layer closer to the first surface S1 side than the active layer 114 by extending in a thickness direction of the laser light generation unit 110 from the second surface S2 toward the first surface S1. The ground electrodes 133a and 133b may be electrically connected to any of the first spacer layer 113 or the first mirror layer 112, for example. The ground electrodes 133a and 133b are ground-side electrodes of the light emitting device 100 and are constituted with a conductive material. The ground electrodes 133a and 133b may be constituted with tungsten (W), titanium (Ti), tantalum (Ta), copper (Cu), gold (Au), or the like, and the insulating layers 131a and 131b may be constituted with an insulating material such as SiO₂, silicon nitride (SiN), or silicon monoxide nitride (SiON).

According to the above layout of the control electrodes 132a and 132b and the ground electrodes 133a and 133b, the current injected into the laser light generation unit 110 from the control electrode 132a passes through the resonance area ra on the control electrode 132a side and is collected by the ground electrode 133a. Meanwhile, the current injected into the laser light generation unit 110 from the control electrode 132b passes through the resonance area ra on the control electrode 132b side and is collected by the ground electrode 133b. Therefore, by producing a difference in voltages applied to each of the control electrodes 132a and 132b, the light emitting device 100 can introduce a bias into the density of the current flowing through the resonance area ra in an arrangement direction of the control electrodes 132a and 132b.

### Deflection Control for Laser Light

Subsequently, deflection of the emission direction of the laser light from the light emitting device 100 will be described with reference to FIGS. 2 and 3. FIG. 2 is an explanatory diagram illustrating a relationship between a voltage V_{bias} applied to the control electrodes 132a and 132b and an optical profile of the laser light L emitted from the laser light generation unit 110. FIG. 3 is an explanatory diagram illustrating a correspondence relationship between the optical profile of the laser light L and a propagation direction of the laser light L.

As illustrated in FIG. 2, a case where sine wave voltages having phases shifted from each other by π are applied to the control electrodes 132a and 132b will be examined. Note that, in FIG. 2, the voltage V_{bias} applied to the control electrode 132a is represented by the broken line, and the voltage V_{bias} applied to the control electrode 132b is represented by the solid line. At this time, a periodic difference is produced in the voltage applied to the control electrodes 132a and 132b according to the lapse of time. This produces a difference in current density in the arrangement direction of the control electrodes 132a and 132b in the resonance area ra of the laser light generation unit 110, and thus, a difference is produced in a light distribution of the generated laser light.

For example, at a time T2 when equal voltages are applied to the control electrodes 132a and 132b, the light distribution of the laser light emitted from the laser light generation unit 110 is symmetrical in the arrangement direction of the control electrodes 132a and 132b. Meanwhile, at a time T1, since a voltage higher than that of the control electrode 132a is applied to the control electrode 132b, the light distribution of the laser light emitted from the laser light generation unit 110 is biased toward the control electrode 132b side. In addition, at a time T3, since a voltage higher than that of the control electrode 132b is applied to the control electrode 132a, the light distribution of the laser light emitted from the laser light generation unit 110 is biased toward the control electrode 132a side.

Here, in a case where the laser light emitted from the laser light generation unit 110 reaches the substrate 120 that absorbs the laser light, the substrate 120 absorbs the laser light to change the refractive index. Specifically, in a case where the substrate 120 absorbs laser light, carriers are generated in the substrate 120 by photoexcitation, and thus the carrier density of the substrate 120 is biased in the arrangement direction of the control electrodes 132a and 132b. Since the refractive index of the substrate 120 lowers as the carrier density rises, in a case where the laser light having the light distribution biased toward the control electrode 132b side enters the substrate 120, the refractive index on the control electrode 132b side becomes lower than the refractive index on the control electrode 132a side, as illustrated in FIG. 3.

As a result, the phase of the laser light going through the substrate 120 propagates later on the control electrode 132b side than on the control electrode 132a side. Accordingly, the phase plane of the laser light proceeding through the substrate 120 is inclined in a way in which the control electrode 132a side advances and the control electrode 132b side falls behind. Since the traveling direction of the laser light is perpendicular to the phase plane, the traveling direction of the laser light having gone through the substrate 120 is deflected toward the control electrode 132b side. Therefore, when the laser light emitted from the laser light generation unit 110 goes through the substrate 120 that absorbs the laser light, the laser light is deflected to the side of an electrode having a higher applied voltage among the control electrodes 132a and 132b and emitted from the substrate 120. This configuration allows the light emitting device 100 to control the emission direction of the emitted laser light with a simpler structure.

As described above, in a case where sine wave voltages having phases shifted from each other by π are applied to the control electrodes 132a and 132b, the difference between the voltages applied to the control electrodes 132a and 132b periodically changes, and the emission direction of the laser light emitted from the substrate 120 also periodically changes. That is, by applying alternating current voltages having different phases to the control electrodes 132a and 132b, the light emitting device 100 can periodically deflect the emission direction of the emitted laser light to the arrangement direction of the control electrodes 132a and 132b.

FIG. 4 illustrates a circuit configuration for applying such alternating current voltages having phases shifted from each other to the control electrodes 132a and 132b. FIG. 4 is a block diagram illustrating a circuit configuration of the light emitting device 100. As illustrated in FIG. 4, the light emitting device 100 further includes a direct current (DC) power supply 151, an alternating current/direct current (AC/DC) conversion unit 152, and a phase delay unit 153.

The DC power supply 151 is, for example, a power source that supplies a direct current voltage, such as a secondary battery. The AC/DC conversion unit 152 is a converter that converts a direct current voltage supplied from the DC power supply 151 into an alternating current voltage. One of the alternating current voltages converted by the AC/DC conversion unit 152 is applied to, for example, the control electrode 132a. In addition, the other of the alternating current voltages is applied to the control electrode 132b after the phase is delayed by the phase delay unit 153. The phase delay unit 153 may be an all-pass filter or the like that changes only the phase with an amplitude fixed, for example.

The light emitting device 100 having the above configuration can periodically deflect the emission direction of the laser light emitted from the substrate 120. Therefore, by making the emitted laser light incident from a focal point onto a collimator lens having a normal direction of the substrate 120 as an optical axis direction, the light emitting device 100 can transform the emitted laser light into a parallel light beam scanning in a direction perpendicular to the optical axis of the collimator lens.

The amount of scanning of the parallel light beam emitted from the collimator lens can be appropriately set according to the application and purpose of the light emitting device 100. For example, the amount of scanning of the parallel light beam emitted from the collimator lens can be controlled by the difference in voltages applied to the control electrodes 132a and 132b, the thickness of the substrate 120, the absorption rate of the substrate 120 for the laser light, and the focal length of the collimator lens.

### 1.2. Modifications

### First Modification

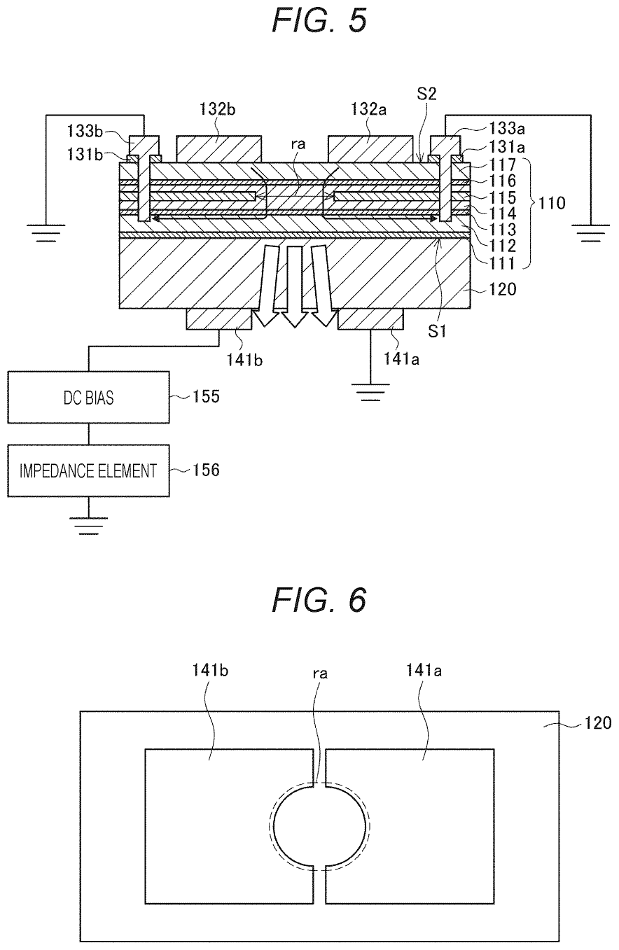

Subsequently, a first modification of the light emitting device 100 according to the present embodiment will be described with reference to FIGS. 5 and 6. FIG. 5 is an explanatory diagram illustrating a cross-sectional configuration of the first modification of the light emitting device 100. FIG. 6 is an explanatory diagram illustrating a planar configuration of detection electrodes 141a and 141b provided on the substrate 120.

As illustrated in FIG. 5, in the first modification of the light emitting device 100, the detection electrodes 141a and 141b are further provided on a surface of the substrate 120 on an opposite side of the surface on which the laser light generation unit 110 is provided.

The detection electrodes 141a and 141b are electrodes that extract carriers generated in the substrate 120 due to absorption of laser light, as a current, to an external circuit of the substrate 120. The light emitting device 100 can evaluate the amount of absorption of the laser light in the substrate 120 by detecting the amount of current extracted by the detection electrodes 141a and 141b and thus can estimate the intensity of the laser light emitted from the laser light generation unit 110. For example, the detection electrodes 141a and 141b may be configured by sequentially laminating titanium-gold (Ti—Au) from the substrate 120 side. The detection electrodes 141a and 141b form a Schottky structure or a metal-insulator-semiconductor (MIS) structure with the substrate 120, thereby being able to extract a current from the substrate 120.

For example, one of the detection electrodes 141a and 141b (detection electrode 141a) may be connected to the ground. In addition, the other of the detection electrodes 141a and 141b (detection electrode 141b) may be connected to an impedance element 156 after a DC bias 155 is applied. For example, the DC bias 155 may apply a direct current voltage of about 5 V. This configuration allows the light emitting device 100 to estimate the amount of current extracted from the substrate 120, from the voltage applied to the impedance element 156, and thus, the light emitting device 100 can estimate the intensity of the laser light emitted from the laser light generation unit 110.

As illustrated in FIG. 6, the detection electrodes 141a and 141b may be provided so as to open an area corresponding to the resonance area ra of the laser light generation unit 110. Specifically, the detection electrodes 141a and 141b may be provided so as to face each other with the resonance area ra interposed therebetween, as well as to open an area smaller than the resonance area ra. In addition, the detection electrodes 141a and 141b may be provided so as to block the laser light emitted from the substrate 120 at any deflection timing. Since the detection electrodes 141a and 141b are provided so as to block the laser light, a current can be extracted from carriers generated during absorption of the laser light, with a depletion layer formed between the detection electrodes 141a and 141b and the substrate 120.

According to the first modification of the light emitting device 100, since the intensity of the laser light emitted from the substrate 120 can be detected more easily, the light emission control for the light emitting device 100 can be performed with higher accuracy.

### Second Modification

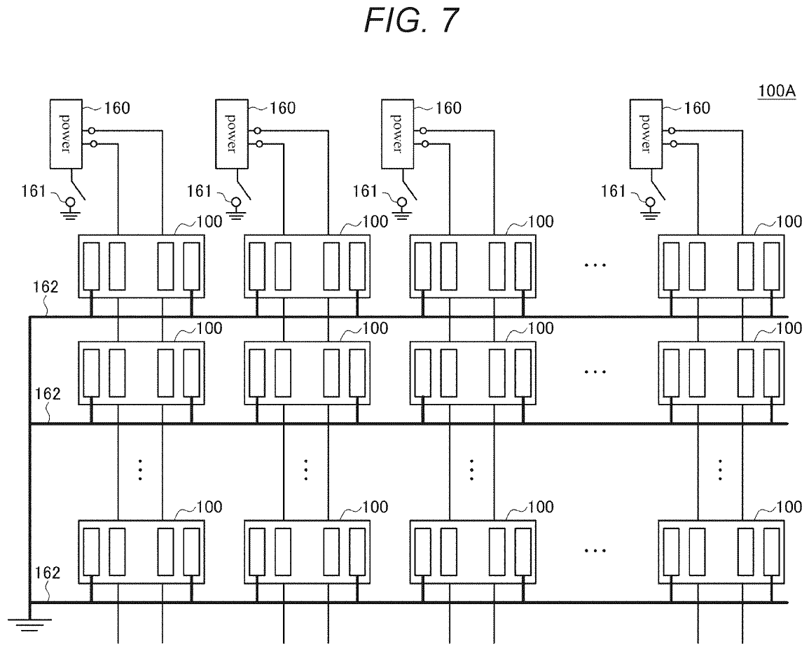

Next, a second modification of the light emitting device 100 according to the present embodiment will be described with reference to FIG. 7. FIG. 7 is a circuit diagram illustrating the second modification of the light emitting device 100.

As illustrated in FIG. 7, in the second modification of the light emitting device, a plurality of the light emitting devices 100 is arranged in a matrix to be configured as a light emitting array 100A. Specifically, in the light emitting array 100A, the control electrodes 132a and 132b of each of the light emitting devices 100 arranged in a column direction (the up-down direction when facing straight to FIG. 7) are connected to the same one of power supplies 160. In addition, in the light emitting array 100A, the ground electrodes 133a and 133b of each of the light emitting devices 100 arranged in a row direction (the lateral direction when facing straight to FIG. 7) are connected to the same one of ground wire lines 162.

By putting a switch 161 of the power supply 160 for each column into a turned-on state, the light emitting array 100A can emit laser light from a plurality of light emitting devices 100 connected to the power supply 160 that has been put into a turned-on state. Therefore, the light emitting array 100A can emit laser light to a two-dimensional plane by sequentially putting the switches 161 of the power supplies 160 into a turned-on state for each column.

According to the second modification of the light emitting device 100, by enabling each of the light emitting devices 100 to have a function of deflecting the laser light, the light emitting array 100A can irradiate a two-dimensional plane with laser light more precisely.

### 2. Second Embodiment

### 2.1. Configuration of Distance Measuring Device

### First Configuration Example

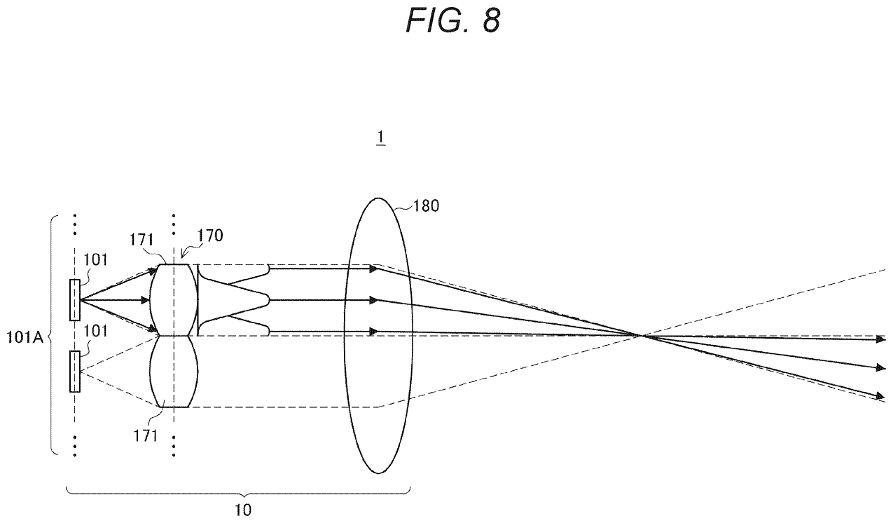

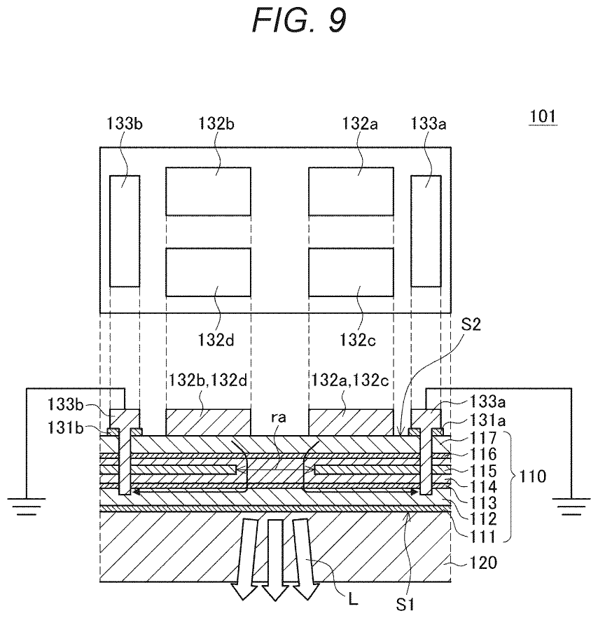

First, a distance measuring device according to a first configuration example of a second embodiment of the present disclosure will be described with reference to FIGS. 8 and 9. FIG. 8 is an explanatory diagram illustrating the distance measuring device 1 according to the first configuration example. FIG. 9 is an explanatory diagram illustrating a top surface configuration and a cross-sectional configuration of a light emitting device 101 according to the first configuration example.

As illustrated in FIG. 8, the distance measuring device 1 according to the first configuration example includes a light projecting unit 10. The light projecting unit 10 includes, for example, a light emitting array 101A, a microlens array 170, and a light projecting lens 180. The distance measuring device 1 is a distance measuring device that measures a distance to a measurement object by irradiating the measurement object with laser light from the light projecting unit 10 and detecting the laser light reflected by the measurement object.

The light emitting array 101A is configured by arranging a plurality of light emitting devices 101 in a matrix. As illustrated in FIG. 9, the light emitting device 101 has a configuration similar to that of the light emitting device 100 according to the first embodiment except that the number of control electrodes 132a, 132b, 132c, and 132d is increased to four. The control electrodes 132a, 132b, 132c, and 132d are laid out in a tetragonal lattice pattern (that is, positions corresponding to vertexes of a quadrangle) on top of a second surface S2 of a laser light generation unit 110.

The light emitting device 101 can deflect the laser light emitted from the light emitting device 101 in a two-dimensional direction, by controlling voltages applied to the control electrodes 132a, 132b, 132c, and 132d.

Specifically, the current injected into the laser light generation unit 110 from the control electrode 132a passes through a resonance area ra on the control electrode 132a side and is collected by a ground electrode 133a. The current injected into the laser light generation unit 110 from the control electrode 132b passes through the resonance area ra on the control electrode 132b side and is collected by a ground electrode 133b. The current injected into the laser light generation unit 110 from the control electrode 132c passes through the resonance area ra on the control electrode 132c side and is collected by the ground electrode 133a. The current injected into the laser light generation unit 110 from the control electrode 132d passes through the resonance area ra on the control electrode 132d side and is collected by the ground electrode 133b. Therefore, by producing a difference in voltages applied to each of the control electrodes 132a, 132b, 132c, and 132d, the light emitting device 101 can introduce a bias into the density of the current flowing through the resonance area ra in the two-dimensional direction. Consequently, the light emitting device 101 can deflect the emission direction of the laser light in any two-dimensional direction, by applying a higher voltage to any two adjacent electrodes among the control electrodes 132a, 132b, 132c, and 132d.

The microlens array 170 is configured by arranging microlenses 171 in a matrix. Each of the microlenses 171 corresponds to one of the light emitting devices 101 included in the light emitting array 101A on a one-to-one basis and is provided so as to have an optical axis coincident with that of the one of the light emitting devices 101. By providing the microlens array 170 such that the light emitting device 101 is laid out at the focal point of the microlens 171, the microlens array 170 can convert the laser light emitted from the light emitting device 101 and deflected into a parallel light beam. The laser light converted into the parallel light beam by the microlens array 170 is projected onto the measurement object by the light projecting lens 180.

The distance measuring device 1 according to the first configuration example can scan a minute area, by temporally changing voltages applied to the control electrodes 132a, 132b, 132c, and 132d provided in the light emitting device 101 and temporally changing the emission direction of the laser light. This configuration allows the distance measuring device 1 according to the first configuration example to enlarge an area that can be irradiated with laser light from each of the light emitting devices 101. Therefore, even in a case where an arrangement pitch of the light emitting devices 101 is large, the distance measuring device 1 according to the first configuration example can acquire distance measurement information with a resolution higher than the arrangement pitch of the light emitting devices 101.

### Second Configuration Example

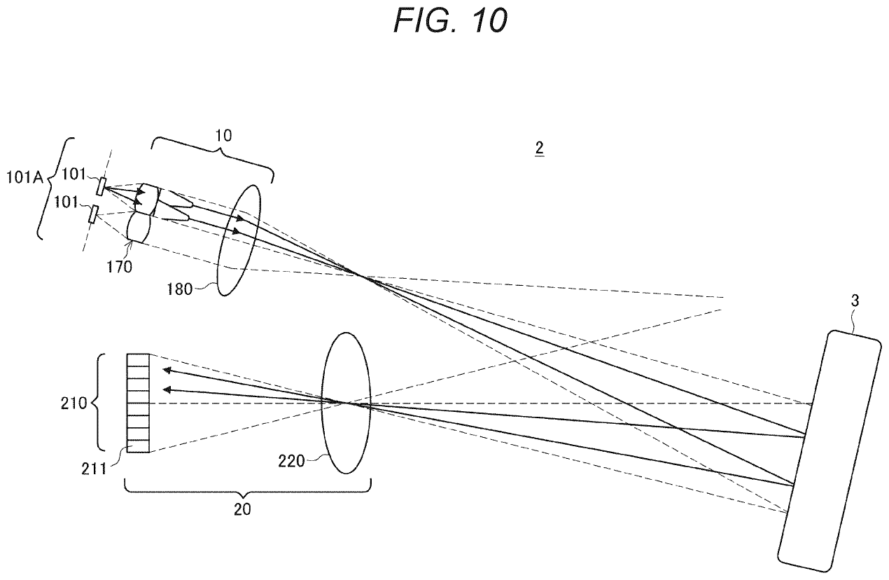

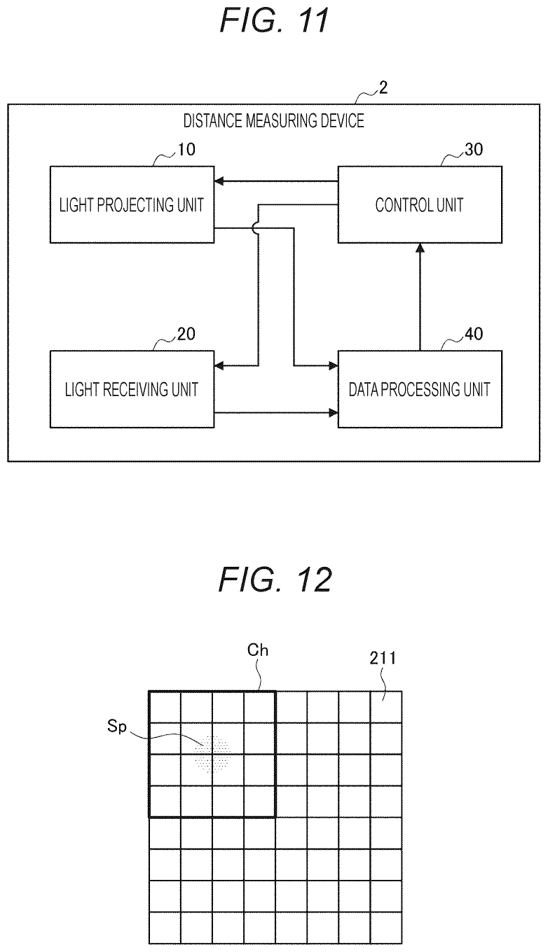

Subsequently, a distance measuring device according to a second configuration example of the second embodiment of the present disclosure will be described with reference to FIGS. 10 and 11. FIG. 10 is an explanatory diagram illustrating a distance measuring device 2 according to the second configuration example of the present embodiment. FIG. 11 is a block diagram illustrating a functional configuration of the distance measuring device 2 according to the second configuration example.

As illustrated in FIG. 10, the distance measuring device 2 according to the second configuration example includes a light projecting unit 10 and a light receiving unit 20. The distance measuring device 2 is a distance measuring device that measures a distance to a measurement object 3 by irradiating the measurement object 3 with laser light from the light projecting unit 10 and detecting the laser light reflected by the measurement object 3 with the light receiving unit 20.

As described in the distance measuring device 1 according to the first configuration example, the light projecting unit 10 includes a light emitting array 101A, a microlens array 170, and a light projecting lens 180. Since the light projecting unit 10 is substantially similar to that of the distance measuring device 1 according to the first configuration example, the description thereof will be omitted here.

The light receiving unit 20 includes a light receiving array 210 and a light receiving lens 220. The light receiving array 210 is configured by arranging a plurality of light receiving elements 211 in a matrix. The light receiving element 211 may be, for example, a single-photon avalanche diode (SPAD) capable of detecting laser light reflected by the measurement object 3 in units of photons.

As illustrated in FIG. 11, in the distance measuring device 2, the light projecting unit 10 and the light receiving unit 20 are controlled by a control unit 30. In addition, the detection result for the laser light by the light receiving unit 20 undergoes data processing in a data processing unit 40 and thereby converted into distance measurement information indicating the distance to the measurement object 3.

The control unit 30 may control the emission direction of the laser light emitted from the light projecting unit 10, as well as control the light receiving elements 211 of the light receiving unit 20 that detect the reflected light from the measurement object 3 on the basis of information regarding the emission direction of the laser light. For example, the control unit 30 may control only the light receiving element 211 onto which the reflected light is estimated to be incident, to a turned-on state, on the basis of the emission direction of the laser light to the measurement object 3. This configuration allows the distance measuring device 2 to suppress the power consumption of the light receiving unit 20.

The data processing unit 40 may derive the distance to the measurement object 3, on the basis of an emission timing of the laser light emitted from the light projecting unit 10 and a light reception timing of the laser light reflected by the measurement object 3 at the light receiving unit 20. Furthermore, the data processing unit 40 can also generate a depth image obtained by incorporating the derived distance to the measurement object 3 in a two-dimensional image.

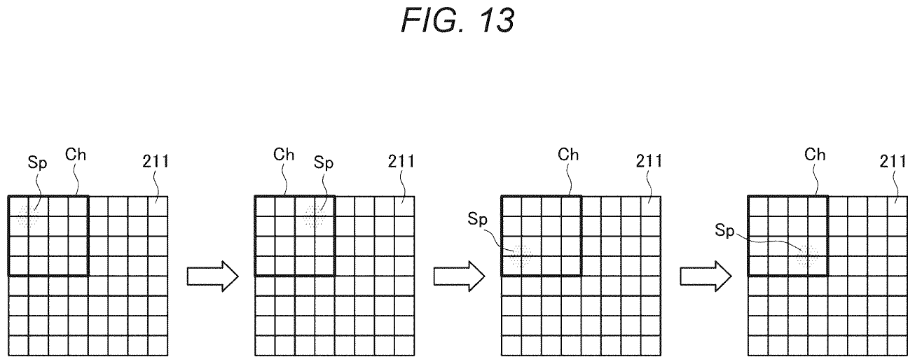

Here, specific control for the light projecting unit 10 and the light receiving unit 20 will be described with reference to FIGS. 12 and 13. FIG. 12 is an explanatory diagram illustrating a relationship between reflected light Sp of the laser light emitted from the light emitting device 101 and the light receiving elements 211. FIG. 13 is an explanatory diagram illustrating deflection control for the laser light emitted from the light emitting device 101 in FIG. 12.

As illustrated in FIG. 12, in the distance measuring device 2, for example, it is assumed that the reflected light Sp of the laser light emitted from one of the light emitting devices 101 has been received by 4×4 light receiving elements 211 (one channel Ch). In addition, it is assumed that the reflected light Sp of the laser light emitted from the one of the light emitting devices 101 has a divergence angle corresponding to 2×2 light receiving elements 211.

In such a case, as illustrated in FIG. 13, by controlling the emission direction of the laser light emitted from the light emitting device 101, the distance measuring device 2 can cause each of four patterns of 2×2 light receiving elements 211 in the channel Ch to receive the reflected light Sp. This configuration allows the distance measuring device 2 to further enhance the resolution of the distance measurement, as compared with a case where the distance measurement in the channel Ch corresponding to 4×4 light receiving elements 211 is performed with one ray of the reflected light Sp of the laser light. In addition, the distance measuring device 2 can also suppress the power consumption by estimating the light receiving element 211 that will receive the reflected light Sp on the basis of the emission direction of the laser light emitted from the light emitting device 101 and putting only the estimated light receiving element 211 into a turned-on state.

Note that, in a case where it has been found that the distance to the measurement object 3 is short, there may be no problem even if the resolution of the distance measurement is low. In such a case, the distance measuring device 2 may perform the distance measurement in the channel Ch corresponding to 4×4 light receiving elements 211 with only one ray of the reflected light Sp of the laser light.

### 2.2. Modifications

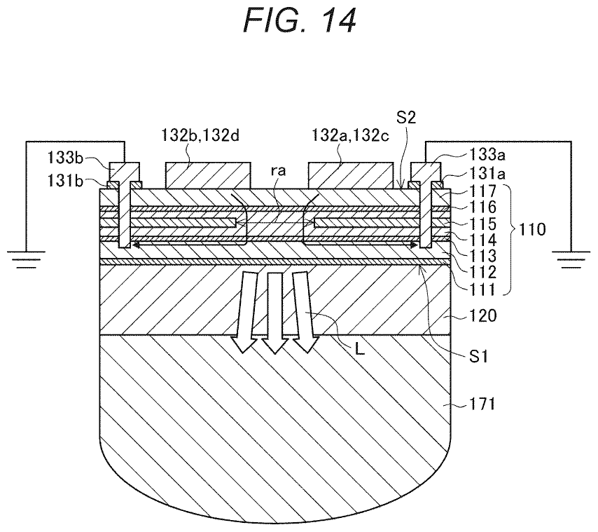

Furthermore, a modification of the light emitting device 101 included in the distance measuring devices 1 and 2 according to the present embodiment will be described with reference to FIG. 14. FIG. 14 is an explanatory diagram illustrating a cross-sectional configuration of a modification of the light emitting device 101.

As illustrated in FIG. 14, in the modification of the light emitting device 101, the microlens 171 is further bonded to a surface of the substrate 120 on an opposite side of the surface on which the laser light generation unit 110 is provided.

The microlens 171 is provided so as to have an optical axis coincident with that of the light emitting device 101. The laser light L emitted from the substrate 120 is converted into a parallel light beam by the microlens 171 and is projected onto the measurement object 3 by the light projecting lens 180 in a subsequent stage.

According to the modification of the light emitting device 101, since the light emitting array 101A and the microlens array 170 can be integrally configured, the light projecting unit 10 can be further downsized. In addition, positional alignment between the light emitting array 101A and the microlens array 170 such that the optical axes coincide with each other between every light emitting device 101 and microlens 171 is no longer involved, and thus, the manufacturing steps can be further simplified.

While the preferred embodiments of the present disclosure have been described above in detail with reference to the accompanying drawings, the technical scope of the present disclosure is not limited to such examples. It is obvious that a person having ordinary knowledge in the technical field of the present disclosure can conceive various alterations or variations within the range of the technical idea described in the claims, and it is naturally understood that these alterations or variations also fall within the technical scope of the present disclosure.

With the technology according to the present disclosure, the light emitting device can deflect the emission direction of the laser light without using a mechanical mechanism or a micromachined optical element. In addition, with the technology according to the present disclosure, since the distance measuring device can scan in the emission direction of the laser light with which the measurement object is irradiated, it is possible to uniformly irradiate the measurement object with the laser light while reducing the divergence angle of the laser light and improving the luminance. Therefore, the distance measuring device using the technology according to the present disclosure can simultaneously improve both the resolution and the distance for distance measurement.

In addition, the effects disclosed in the present description are merely illustrative or exemplary, and are not restrictive. In other words, the technology according to the present disclosure may achieve other effects obvious to those skilled in the art from the description in the present description, in addition to or instead of the effects described above.

Note that the configurations as mentioned below also fall within the technical scope of the present disclosure.

(1)

A light emitting device including:
a laser light generation unit that causes laser light to resonate in a resonance area on a first surface and a second surface facing each other, and emits the laser light from the first surface;
a substrate that is provided on the first surface of the laser light generation unit, and absorbs a part of the emitted laser light while transmitting the laser light; and
a plurality of control electrodes that is provided on the second surface of the laser light generation unit, and faces each other with the resonance area interposed between the control electrodes.
   (2)

The light emitting device according to (1) above, in which the laser light generation unit includes an active layer that causes the laser light to arise, and a pair of mirror layers provided with the active layer interposed between the mirror layers in a facing direction of the first surface and the second surface, and causes the laser light to resonate with the pair of mirror layers.

(3)

The light emitting device according to (2) above, in which the laser light generation unit further includes a current confinement layer having an electrical resistance higher than the electrical resistance of the active layer, inside the active layer, and
the resonance area includes an area where the active layer is narrowed by the current confinement layer.
   (4)

The light emitting device according to (2) or (3) above, further including a ground electrode provided to extend in a thickness direction of the laser light generation unit and electrically connected to a layer of the laser light generation unit on a side closer to the first surface than the active layer.

(5)

The light emitting device according to (4) above, in which the ground electrodes are provided corresponding to each of the plurality of control electrodes, and are provided on an opposite side of the resonance area with respect to the corresponding control electrodes.

(6)

The light emitting device according to any one of (1) to (5) above, in which the laser light is emitted from the substrate while being inclined in an arrangement direction of the plurality of control electrodes, according to a difference in voltages applied to each of the plurality of control electrodes.

(7)

The light emitting device according to (6) above, in which alternating current voltages having phases different from each other are separately applied to the plurality of control electrodes.

(8)

The light emitting device according to any one of (1) to (7) above, in which a detection electrode that extracts a current from the substrate is further provided on a surface of the substrate on an opposite side of a surface on which the laser light generation unit is provided.

(9)

A distance measuring device including
a light projecting unit configured by arranging a plurality of light emitting devices in an array, in which
each of the plurality of light emitting devices includes:
a laser light generation unit that causes laser light to resonate in a resonance area on a first surface and a second surface facing each other, and emits the laser light from the first surface;
a substrate that is provided on the first surface of the laser light generation unit, and absorbs a part of the emitted laser light while transmitting the laser light; and
a plurality of control electrodes that is provided on the second surface of the laser light generation unit, and faces each other with the resonance area interposed between the control electrodes.
   (10)

The distance measuring device according to (9) above, in which each of the plurality of light emitting devices includes four of the control electrodes, and

each of the plurality of light emitting devices causes an emission direction of the laser light to be inclined in any direction, according to voltages applied to the four of the control electrodes.

(11)

The distance measuring device according to (9) or (10) above, further including an optical system that shapes the laser light emitted from each of the plurality of light emitting devices.

(12)

The distance measuring device according to (11) above, in which each of lenses of a microlens array included in the optical system is optically aligned with one of the plurality of light emitting devices.

(13)

A distance measuring device
including:
a light projecting unit that is configured by arranging a plurality of light emitting devices in an array, and projects projection light onto an object; and
a light receiving unit that receives the projection light reflected by the object, in which
each of the plurality of light emitting devices includes:
a laser light generation unit that causes laser light to resonate in a resonance area on a first surface and a second surface facing each other, and emits the laser light from the first surface;
a substrate that is provided on the first surface of the laser light generation unit, and absorbs a part of the emitted laser light while transmitting the laser light; and
a plurality of control electrodes that is provided on the second surface of the laser light generation unit, and faces each other with the resonance area interposed between the control electrodes.

### REFERENCE SIGNS LIST

1, 2 Distance measuring device
3 Measurement object
10 Light projecting unit
20 Light receiving unit
100, 101 Light emitting device
100A, 101A Light emitting array
110 Laser light generation unit
111 Buffer layer
112 First mirror layer
113 First spacer layer
114 Active layer
115 Current confinement layer
116 Second spacer layer
117 Second mirror layer
120 Substrate
132a, 132b, 132c, 132d Control electrode
133a, 133b Ground electrode
141a, 141b Detection electrode
170 Microlens array
171 Microlens
180 Light projecting lens
210 Light receiving array
211 Light receiving element
220 Light receiving lens

1. A light emitting device comprising:
a laser light generation unit that causes laser light to resonate in a resonance area on a first surface and a second surface facing each other, and emits the laser light from the first surface;
a substrate that is provided on the first surface of the laser light generation unit, and absorbs a part of the emitted laser light while transmitting the laser light; and
a plurality of control electrodes that is provided on the second surface of the laser light generation unit, and faces each other with the resonance area interposed between the control electrodes.

2. The light emitting device according to claim 1, wherein the laser light generation unit includes an active layer that causes the laser light to arise, and a pair of mirror layers provided with the active layer interposed between the mirror layers in a facing direction of the first surface and the second surface, and causes the laser light to resonate with the pair of mirror layers.

3. The light emitting device according to claim 2, wherein the laser light generation unit further includes a current confinement layer having an electrical resistance higher than the electrical resistance of the active layer, inside the active layer, and
the resonance area includes an area where the active layer is narrowed by the current confinement layer.

4. The light emitting device according to claim 2, further comprising a ground electrode provided to extend in a thickness direction of the laser light generation unit and electrically connected to a layer of the laser light generation unit on a side closer to the first surface than the active layer.

5. The light emitting device according to claim 4, wherein the ground electrodes are provided corresponding to each of the plurality of control electrodes, and are provided on an opposite side of the resonance area with respect to the corresponding control electrodes.

6. The light emitting device according to claim 1, wherein the laser light is emitted from the substrate while being inclined in an arrangement direction of the plurality of control electrodes, according to a difference in voltages applied to each of the plurality of control electrodes.

7. The light emitting device according to claim 6, wherein alternating current voltages having phases different from each other are separately applied to the plurality of control electrodes.

8. The light emitting device according to claim 1, wherein a detection electrode that extracts a current from the substrate is further provided on a surface of the substrate on an opposite side of a surface on which the laser light generation unit is provided.

9. A distance measuring device comprising
a light projecting unit configured by arranging a plurality of light emitting devices in an array, wherein
each of the plurality of light emitting devices includes:
a laser light generation unit that causes laser light to resonate in a resonance area on a first surface and a second surface facing each other, and emits the laser light from the first surface;
a substrate that is provided on the first surface of the laser light generation unit, and absorbs a part of the emitted laser light while transmitting the laser light; and
a plurality of control electrodes that is provided on the second surface of the laser light generation unit, and faces each other with the resonance area interposed between the control electrodes.

10. The distance measuring device according to claim 9, wherein each of the plurality of light emitting devices includes four of the control electrodes, and
each of the plurality of light emitting devices causes an emission direction of the laser light to be inclined in any direction, according to voltages applied to the four of the control electrodes.

11. The distance measuring device according to claim 9, further comprising an optical system that shapes the laser light emitted from each of the plurality of light emitting devices.

12. The distance measuring device according to claim 11, wherein each of lenses of a microlens array included in the optical system is optically aligned with one of the plurality of light emitting devices.

13. A distance measuring device
comprising:
a light projecting unit that is configured by arranging a plurality of light emitting devices in an array, and projects projection light onto an object; and
a light receiving unit that receives the projection light reflected by the object, wherein
each of the plurality of light emitting devices includes:
a laser light generation unit that causes laser light to resonate in a resonance area on a first surface and a second surface facing each other, and emits the laser light from the first surface;
a substrate that is provided on the first surface of the laser light generation unit, and absorbs a part of the emitted laser light while transmitting the laser light; and
a plurality of control electrodes that is provided on the second surface of the laser light generation unit, and faces each other with the resonance area interposed between the control electrodes.
